(19) United States
(12) Patent Application Publication
(10) Pub. No.: US 2025/0287707 A1
(43) Pub. Date: Sep. 11, 2025

(54) Miniature Imaging Sensor Illumination Package And Manufacturing Method Thereof

(71) Applicant: Medimaging Integrated Solution, Inc., Hsinchu (TW)

(72) Inventors: SHANGYI WU, HSINCHU (TW); HSIN-HSIEN HSIEH, HSINCHU (TW); CHIH LUNG HSU, HSINCHU (TW); TSENG SHEN TSENG, HSINCHU (TW)

(21) Appl. No.: 18/925,650

(22) Filed: Oct. 24, 2024

(30) Foreign Application Priority Data
Mar. 7, 2024 (TW) 113108476

(51) Int. Cl. H01L 27/146

(52) U.S. Cl. CPC H10F 39/198; H10F 39/026; H10F 39/811

(57) ABSTRACT

A miniature imaging sensor illumination package includes a substrate, an illumination module, an image sensing module, and an encapsulating medium. The substrate has multiple conductive routings. The illumination module includes a supporter, a light-emitting element, and conductors. The light-emitting element is located on the top surface of the supporter. The conductors are arranged inside the supporter and correspondingly positioned under the light-emitting element. The first end of the conductor is electrically connected to the light-emitting element, and the second end is electrically connected to the conductive routings. A connection part is provided between the conductors to separately connect a part of the conductors. The image sensing module is located on the substrate and adjacent to the illumination module. The encapsulating medium is positioned between and around the illumination module and the image sensing module.

### BACKGROUND OF THE INVENTION

### 1. Field of the Invention

The present invention provides an endoscopic imaging sensor illumination module, particularly a miniature imaging sensor illumination package and a manufacturing method thereof.

### 2. Description of the Prior Art

At present, the imaging sensor illumination module of endoscopes confronts many technical problems. These problems affect the performance and fabrication process of the module. In structure, the module has a larger size after package or assemblage. The larger-size module is hard to facilitate miniaturization of endoscopes. Contrarily, it limits the flexibility of utilizing the module. The light-emitting diode (LED) is used as the illumination element of the imaging sensor illumination module of endoscopes. However, the position of LED is likely to affect the performance of the image sensing module. For example, an unsuitable position of LED may result in shadows or blind spots of the image sensor and affect the accuracy and resolution of image sensing.

In operation, LED generates heat in usage. Poor heat dissipation may degrade the performance of LED, shorten the service life of LED, and cause the damage of LED. In general, LED is disposed on a flexible printed circuit or a printed circuit board (PCB). However, LED is less likely to dissipate heat effectively in such an environment, which may raise the temperature of the optical image module of the endoscope and affect the stability and life of LED. In the conventional technology, the height of LED and the height of the image sensor are fixed. The ordinary design is unlikely to adjust the relative distance of LED and the image sensor. Thus, the parameters of light sources and illuminators are hard to adjust or optimize. Then, the sensing performance and image quality may be affected. In the case that the image sensor and LED are disposed on a substrate, if there is no light shield material between the image sensor and LED, the light of LED may enter the image sensor and generate stray light. The stray light may affect the image quality also.

In fabrication, if the image sensor and LED are disposed on FPC, a cap is normally used as a light shield layer to cover the image sensor. If the manufacturer intends to raise the position of LED, FPC will be bent and then fixed. However, the bent FPC must be encased and fixed with a plastic material in a mold injection method. Such a measure leads to a large module size, a complicated fabrication process, and a difficult assemblage, which not only increase the cost but also affect the consistency of products. If an adapter is used in soldering signal cables, it may increase the fabrication steps and raise the impedance of signal paths. Thus, the accuracy of data and signal transmission may be affected. Accordingly, the Inventors improve the technology to miniaturize the endoscopic imaging sensor illumination module and enhance the performance and reliability of the imaging sensor illumination module so as to overcome the abovementioned problems.

### SUMMARY OF THE INVENTION

One objective of the present invention is to provide a miniature imaging sensor illumination package and a manufacturing method thereof, wherein all the illumination light sources can keep operating while a single routing fails to work, and the present invention is exempted from the conventional problem that each LED light source needs its own power input, and wherein the present invention can prevent stray light from entering the image sensing module, increase the adhesion of the illumination light source, enhance the image quality, minimize the overall size of the module, favor designing the front bent region of an endoscope, and achieve the smallest radius of curvature.

According to the abovementioned objective, the present invention proposes a miniature imaging sensor illumination package, which comprises a substrate, an illumination module, an image sensing module, and an encapsulating medium. The substrate has a plurality of conductive routings and at least one positioning hole. The illumination module is disposed on the substrate and adjacent to at least one positioning hole. The illumination module includes a supporter, at least one light-emitting element, and a plurality of conductors. The supporter has a top surface and a bottom surface, which are vertically opposite to each other, and the bottom surface is disposed on the substrate. The light-emitting element is disposed on the top surface of the supporter. Each light-emitting element has a light-emitting face. The conductors are arranged in the interior of the supporter and located corresponding to the bottom of the light-emitting element. Each conductor has a first end and a second end opposite to the first end. The first end is exposed on the top surface and electrically connected with at least one light-emitting element. The second end is exposed on the bottom surface and electrically connected with a plurality of conductive routings on the substrate. Connection routings are arranged among the plurality of conductors and respectively connected with a portion of the plurality of conductors. The image sensing module has a sensing face and a connection face, which are vertically opposite to each other. The image sensing module is disposed on the substrate and adjacent to at least one positioning hole. The image sensing module neighbors the illumination module. The connection face is connected with the plurality of conductive routings. The sensing face is higher than the light-emitting face of at least one light-emitting element. The encapsulating medium covers the spaces between and around the illumination module and the image sensing module and reveals the sensing face of the image sensing module.

In one embodiment, the miniature imaging sensor illumination package further comprises an isolation medium, which is arranged between the top surface of the substrate and the connection face of the image sensing module.

In one embodiment, the substrate has a first surface and a second surface, which are vertically opposite to each other. The first surface has a plurality of conductive routings. The second surface has a plurality of backside routings disposed on the locations corresponding to the plurality of conductive routings. Each conductive routing and the corresponding backside routing are connected to each other inside the substrate.

In one embodiment, the miniature imaging sensor illumination package further comprises an encapsulating mold, which are movably placed on the substrate. The encapsulating mold includes a body, at least one insertion member, and a through-hole. The insertion member is disposed on the bottom of the body and placed into at least one corresponding positioning hole. The through-hole is formed in the body, and the border of the through-hole neighbors at least one insertion member. The through-hole surrounds the illumination module and the image sensing module, whereby the illumination module and the image sensing module are inserted into the through-hole. The encapsulating medium is filled into the interior of the through-hole and the spaces between and around the illumination module and the image sensing module. The encapsulating mold is removed after the encapsulating medium is cured or after the cutting process is completed.

According to the abovementioned objective, the present invention also proposes a manufacturing method of a miniature imaging sensor illumination package, which comprises steps:
providing a substrate, which has a plurality of conductive routings and at least one positioning hole;
disposing an illumination module on the substrate, wherein the illumination module includes at least one supporter, at least one light-emitting element, and a plurality of conductors;
disposing an image sensing module on the substrate and near the illumination module, wherein a connection face of the image sensing module is connected with the plurality of conductive routings; a sensing face of the image sensing module is higher than a light-emitting face of the at least one light-emitting element; and
forming an encapsulating medium between and around the illumination module and the image sensing module.

The abovementioned step of disposing an illumination module on the substrate further comprises steps:
forming a plurality of conductors in the interior of the supporter, wherein the plurality of conductors are disposed under at least one light-emitting element correspondingly; first ends of the plurality of conductors are disposed on a top surface of the supporter and electrically connected with at least one light-emitting element; second ends of the plurality of conductors are disposed on a bottom surface of the supporter and electrically connected with the plurality of conductive routings of the substrate; a connection routing is disposed between the conductors; the connection routing is connected with a portion of the conductors; and
disposing at least one light-emitting element on the top surface of the supporter.

According to the abovementioned objective, the present invention further proposes a manufacturing method of a miniature imaging sensor illumination package, which comprises steps:
providing a substrate, which has a plurality of conductive routings and at least one positioning hole;
disposing a plurality of illumination modules and a plurality of image sensing modules on the substrate, wherein the image sensing module neighbors the illumination module; the connection face of each of the plurality of image sensing modules is connected with the plurality of conductive routings; the sensing face of the image sensing module is higher than the light-emitting face of at least one light-emitting element; and
cutting the substrate along a plurality of cutting marks to form a plurality of miniature imaging sensor illumination packages each having a plurality of illumination modules and an image sensing modules.

Thus, the present invention provides a miniature imaging sensor illumination package and a manufacturing method thereof, which can reduce the overall volume, minimize the size of the miniature imaging sensor illumination package, enhance the image quality, and protect the image sensing module from being affected by stray light. Further, the design of the routings of the supporter makes the routings connected in parallel on the surface or in the interior, such as the interconnection of anode electrodes and the interconnection of cathode electrodes, whereby while a single routing fails, all the illumination light sources can keep on working normally.

The objective, technologies, features and advantages of the present invention will become apparent from the following description in conjunction with the accompanying drawings wherein certain embodiments of the present invention are set forth by way of illustration and example.

### BRIEF DESCRIPTION OF THE DRAWINGS

The foregoing conceptions and their accompanying advantages of this invention will become more readily appreciated after being better understood by referring to the following detailed descriptions, in conjunction with the accompanying drawings, wherein

FIG. 1 is a perspective view schematically showing a miniature imaging sensor illumination package according to one embodiment of the present invention;

FIG. 2A is a diagram schematically showing a substrate of a miniature imaging sensor illumination package according to one embodiment of the present invention;

FIG. 2B is a diagram schematically showing a local area of a second surface of the substrate shown in FIG. 2A;

FIG. 3 is a diagram schematically showing an illumination module of a miniature imaging sensor illumination package according to one embodiment of the present invention;

FIGS. 4A-4D are diagrams respectively schematically showing different embodiments of an illumination module of a miniature imaging sensor illumination package of the present invention;

FIG. 5 is a diagram schematically showing a packaging operation of a miniature imaging sensor illumination package according to one embodiment of the present invention;

FIG. 6 is a diagram schematically showing of Local Area R2 shown in FIG. 5;

FIG. 7 is a first diagram schematically showing a packaging operation of a miniature imaging sensor illumination package according to another embodiment of the present invention;

FIG. 8 is a second diagram schematically showing the packaging operation of a miniature imaging sensor illumination package according to the same embodiment shown in FIG. 7;

FIG. 9 is a perspective view schematically showing a miniature imaging sensor illumination package according to another embodiment of the present invention;

FIG. 10 is a cross-sectional view of the miniature imaging sensor illumination package shown in FIG. 9;

FIG. 11 is a diagram schematically showing steps of manufacturing miniature imaging sensor illumination packages according to a first embodiment of the present invention;

FIG. 12 is a flowchart of sub-steps of Step S11 in FIG. 11.

FIG. 13 is a flowchart of sub-steps of Step S12 in FIG. 11.

FIG. 14 is a diagram schematically showing steps of manufacturing miniature imaging sensor illumination packages according to a second embodiment of the present invention; and

FIG. 15 is a diagram schematically showing steps of manufacturing miniature imaging sensor illumination packages according to a third embodiment of the present invention.

### DESCRIPTION OF THE PREFERRED EMBODIMENTS

The embodiments of the present invention will be further demonstrated in details hereinafter in cooperation with the corresponding drawings. In the drawings and the specification, the same numerals represent the same or the like elements as much as possible. For simplicity and convenient labelling, the shapes and thicknesses of the elements may be exaggerated in the drawings. It is easily understood: the elements belonging to the conventional technologies and well known by the persons skilled in the art may be not particularly depicted in the drawings or described in the specification. Various modifications and variations made by the persons skilled in the art according to the contents of the present invention are to be included by the scope of the present invention.

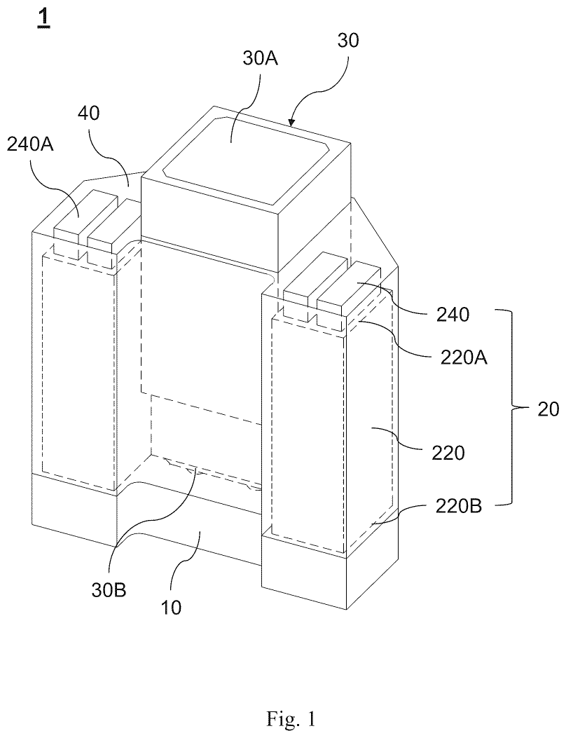

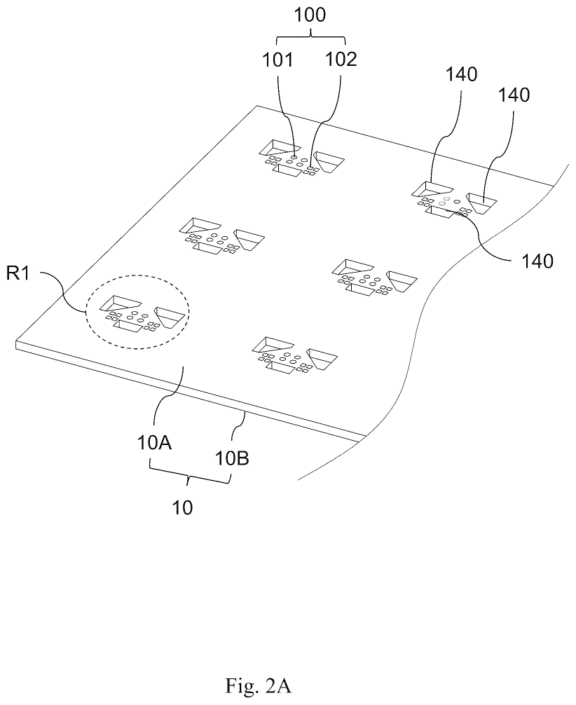

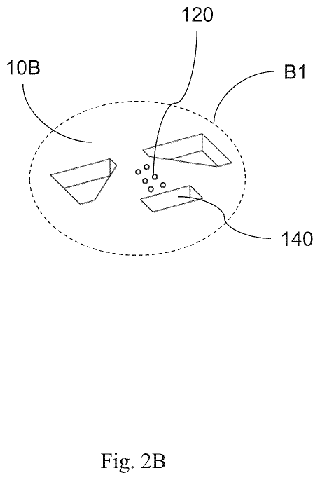

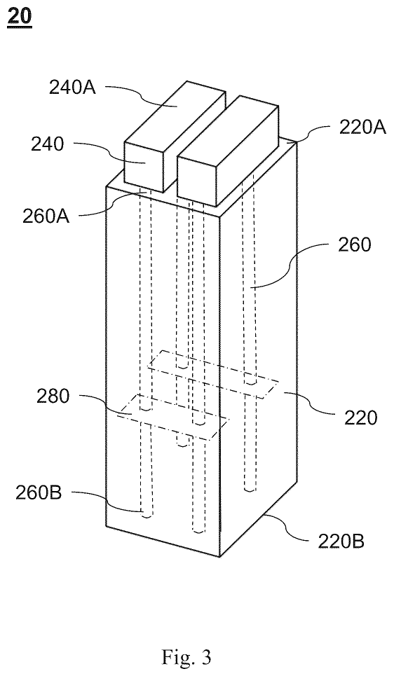

Below is introduced an embodiment of a miniature imaging sensor illumination package of the present invention. Refer to FIG. 1, FIG. 2A, FIG. 2B, and FIG. 3. FIG. 1 is a diagram schematically showing an overall appearance of a miniature imaging sensor illumination package 1. FIG. 2A is a diagram schematically showing a substrate 10. FIG. 2B is a diagram schematically showing a local area of a second surface 10B of the substrate 10. FIG. 3 is a diagram schematically showing an illumination module 20. The miniature imaging sensor illumination package 1 comprises a substrate 10, an illumination module 20, an image sensing module 30, and an encapsulating medium 40. The substrate 10 has a plurality of conductive routings 100 (shown in FIG. 2A) and at least one positioning hole 140 (shown in FIG. 2A). The illumination module 20 is disposed on the substrate 10 and adjacent to the positioning hole 140. As shown in FIG. 3, the illumination module 20 includes a supporter 220, at least one light-emitting element 240, and a plurality of conductors 260. The supporter 220 has a top surface 220A and a bottom surface 220B, which are opposite to each other. The bottom surface 220B is disposed on the substrate 10. The light-emitting element 240 is disposed on the top surface 220A of the supporter 220. The light-emitting element 240 has a light-emitting face 240A. The conductors 260 are arranged in the interior of the supporter 220 and under the corresponding light-emitting element 240. As shown in FIG. 3, each conductor 260 has a first end 260A and a second end 260B, which are opposite to each other. The first end 260A is revealed on the top surface 220A and electrically connected with at least one light-emitting element 240. The second end 260B is revealed on the bottom surface 220B and electrically connected with the plurality of conductive routings 100 of the substrate 10. Connection routings 280 are arranged among the plurality of conductors 260 and respectively connected with a portion of the plurality of conductors 260. The image sensing module 30 has a sensing face 30A and a connection face 30B, which are opposite to each other. The image sensing module 30 is disposed on the substrate 10 and adjacent to the positioning hole 140. The image sensing module 30 neighbors the illumination module 20. The connection face 30B is connected with the plurality of conductive routings 100 of the substrate 10, as show in FIG. 2A. The sensing face 30A is higher than the light-emitting face 240A of the light-emitting element 240. The encapsulating medium 40 covers the spaces between and around the illumination module 20 and the image sensing module 30 and reveals the sensing face 30A of the image sensing module 30, whereby to prevent the light source of the illumination module 20 from entering the image sensing module 30 lest stray light enter the image sensing module 30 and enhance the adhesion of the light source of the illumination module 20. The encapsulating medium 40 may be formed via filling a non-transparent (semi-transparent or opaque) material into the spaces between and around the illumination module 20 and the image sensing module 30 and curing the material.

As shown in FIG. 1, the substrate 10 has at least one positioning hole 140. The positioning hole 140 may be a perforated through-hole or a positioning mark. In the embodiment, the positioning hole 140 is in form of a perforated through-hole. However, the present invention does not constrain that the positioning hole 140 must be a perforated through-hole. The illumination module 20 and the image sensing module 30 may be disposed on the border of the positioning hole 140, and the positioning hole 140 is adjacent to the illumination module 20 and the image sensing module 30. The positioning hole 140 will be cut off in the cutting process. In the case that the miniature imaging sensor illumination package 1 is applied to an endoscope, although the signal transmission cables of the endoscope and the power cords of the illumination light source are not illustrated in the drawings, the persons having ordinary knowledge of the field should be able to learn from the text that the bottom of the miniature imaging sensor illumination package 1 is connected with signal transmission cables of the endoscope and the power cords of the illumination light source. The signal transmission cables and the power cords of the illumination light source may be connected with a plurality of backside routings 120 on the back side of the substrate 10 in a high-temperature soldering method, as shown in FIG. 2B. The backside routing 120 may be a metal electrode extended outward from the substrate 10 toward different directions. The backside routings 120 may be made of different materials according to requirements. After the cables and power cords are soldered to the backside routings 120 of the substrate 10, the solder points may be fixed with a resin material, which may be a UV-cured resin material or a thermoset resin material. Alternatively, a mold is used to assist in fixing the solder points, wherein a resin material is filled into the mold to form a resin body, which has a specified shape, on the back of the miniature imaging sensor illumination package 1 to cover and protect a portion of the routings. In the present invention, the cables and power cords are directly connected in a soldering method on the back side of the miniature imaging sensor illumination package 1, whereby the present invention can avoid the signal loss caused by using an adapter board, increase the signal-to-noise ratio, and enhance the image quality, whereby the present invention can minimize the length of the miniature imaging sensor illumination package 1 to favor the design of the front bent region of the endoscope and achieve the smallest radius of curvature.

As shown in FIG. 2A and FIG. 2B, the substrate 10 has a first surface 10A and a second surface 10B, which are opposite to each other. The first surface 10A has a plurality of conductive routings 100. The second surface 10B has a plurality of backside routings 120 formed on the positions corresponding to the plurality of conductive routings 100. The conductive routings 100 are respectively connected with the corresponding backside routings 120 in the interior of the substrate 10. FIG. 2A shows a local region R1 on the front surface 10A of the substrate 10. FIG. 2B shows a local region B1, which are corresponding to the local area R1 but on the second surface 10B of the substrate 10. It should be understood by the persons having ordinary knowledge of the field: the conductive routings 100 are respectively connected with the corresponding backside routings 120 inside the substrate 10. Thus, its details will not repeat herein. The substrate 10 may be but is not limited to be a ceramic substrate, a printed circuit board (PCB), or a flexible printed circuit (FPC).

The plurality of conductive routings 100 may be arranged in array. The plurality of conductive routings 100 includes conductive routings 101 of the image sensing module 30 and conductive routings 102 of the illumination module 20. The conductive routings 101 of the image sensing module 30 are disposed on the first surface 10A of the substrate 10 and corresponding to the image sensing module 30. The conductive routings 102 of the illumination module 20 are disposed on the lateral sides or perimeters of the conductive routings 101 of the image sensing module 30. The second surface 10B of the substrate 10 has metal routings able to output image signals and input power to the illumination light source. The metal routings on the top surface and bottom surface are interconnected through the routings inside the substrate 10.

In the embodiment, the positioning holes 140 are three perforated holes. The positioning holes 140 can effectively assist in the positioning of the illumination module 20 and the image sensing module 30, favoring the space design of the miniature imaging sensor illumination package 1 and saving the materials.

As shown in FIG. 3, the top surface 220A, the interior, and the bottom surface 220B of the supporter 220 have the conductors 260. The light source of the light-emitting element 240 is disposed on the top surface 220A, and the electric connection thereof is extended to the routings on the bottom surface 220B of the supporter 220 through the internal conductors 260. The altitude of the supporter 220 may be adjusted in advance according to requirement. The illumination module 20 has one or more light-emitting elements 240 as the illumination light sources. The light sources may be connected in parallel through the internal, top and bottom routings of the supporter 220. Via the design of the internal routings of the supporter 220, the routings of the light-emitting elements 240 around the image sensing module 30 may be reconfigured/reconnected to form at least one additional group of driving routings. The present invention is exempted from using the conventional technology that one light source needs one group of cables but may supply power using the cables matching the number of the routings.

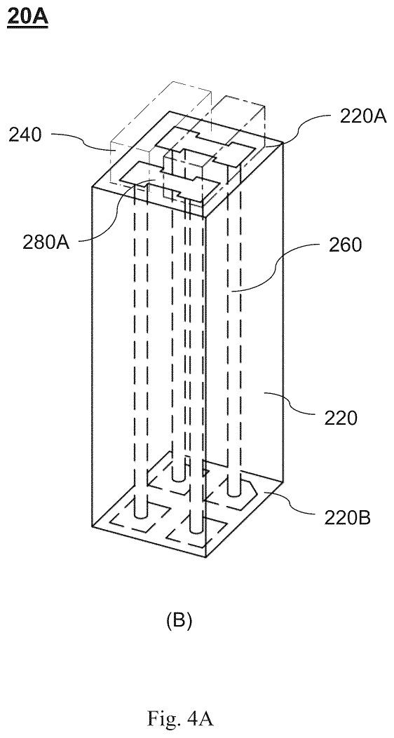

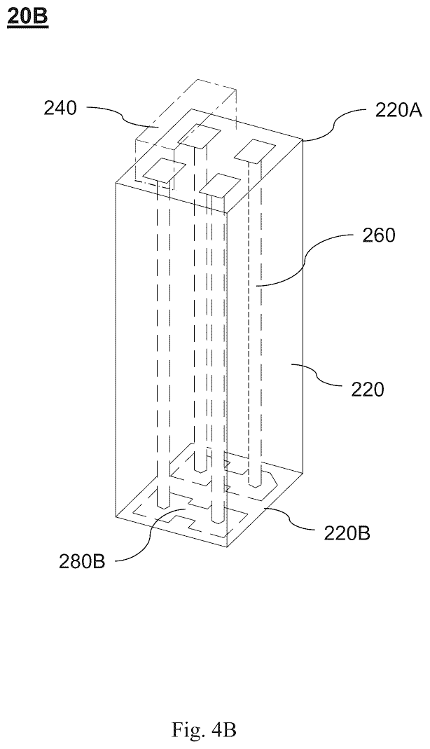

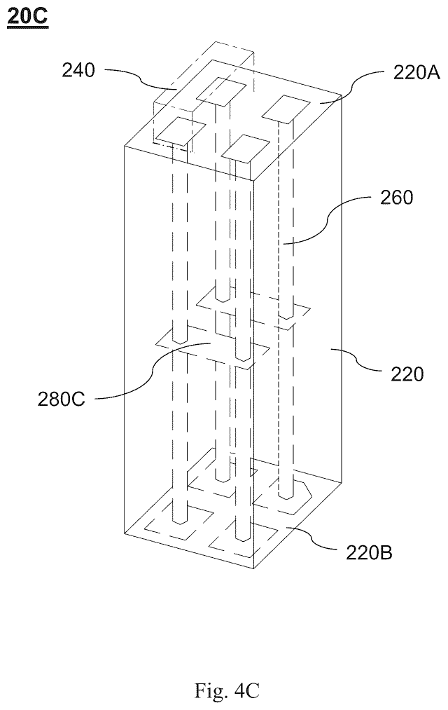

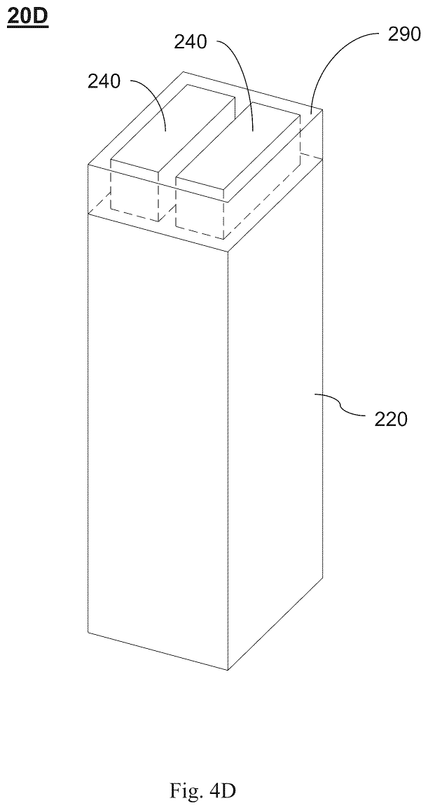

Refer to FIGS. 4A-4D. Below are introduced various embodiments of the illumination module. FIG. 4A is a diagram schematically showing an illumination module 20A. FIG. 4B is a diagram schematically showing an illumination module 20B. FIG. 4C is a diagram schematically showing an illumination module 20C. The illumination module 20A, the illumination module 20B and the illumination module 20C are different in the connection routing. In order to illustrate various patterns of the illumination module, the supporter 220 is represented as a transparent body in the drawings. However, such a representation is not to limit the material or characteristics of the supporter 220. As shown in FIG. 4A, in the illumination module 20A, the connection routings 280A are disposed at the first ends 260A of the conductors 260. As shown in FIG. 4B, in the illumination module 20B, the connection routings 280B are disposed at the second ends 260B of the conductors 260. As shown in FIG. 4C, in the illumination module 20C, the connection routings 280C are disposed at positions between the first ends 260A and second ends 260B of the conductors 260. The configurations of the illumination modules 20A, 20B and 20C may be used to connect a portion of the conductors 260 in parallel, wherein an anode electrode is connected with another anode electrode; a cathode electrode is connected with another cathode electrode, whereby while a single routing fails, all the light sources of the light-emitting elements 240 can still work. Besides, the light-emitting elements 240 (such as LEDs) of the illumination module 20 may emit lights having an identical wavelength/color temperature or emit lights respectively having different wavelengths/color temperatures. The light-emitting elements 240 may be switched on separately or simultaneously to meet different applications.

FIG. 4D shows another pattern of the illumination module. The illumination module shown in FIG. 4D is different from the abovementioned illumination modules in a packing medium 290. As shown in FIG. 4D, in the illumination module 20D, the packing medium 290 covers a space between the light-emitting elements 240 and the spaces around the light-emitting elements 240. The packing medium 290 is formed via curing a transparent or semi-transparent packing material. The packing medium 290 is disposed on the supporter 220, but the packing medium 290 is not allowed to cover the region above the light source lest the light extraction efficiency be reduced. Further, the packing medium 290 may assist in homogenizing the distribution of the light field. The light-emitting element 240, which functions as an illumination light source, may be but is not limited to be a light-emitting diode (LED) chip, a fluorescent powder-coated LED chip, or a light-emitting element carried by another supporter.

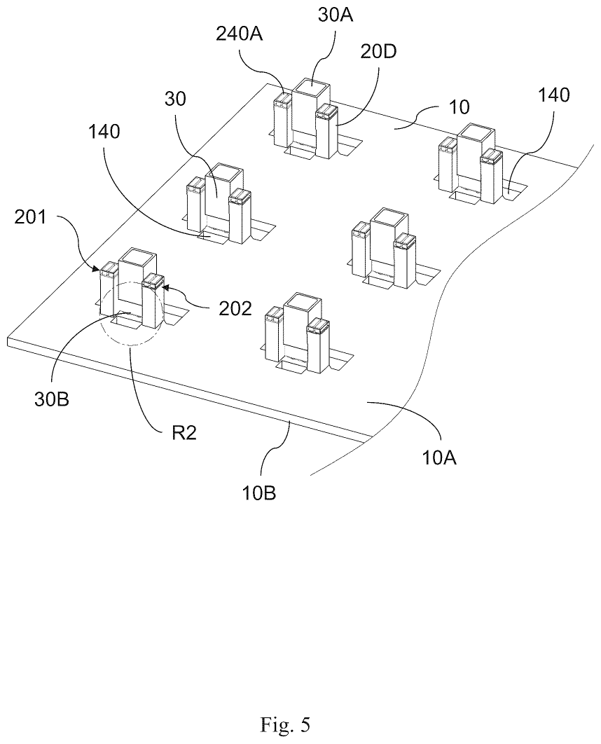

Refer to FIG. 5. The image sensing module 30 and the illumination modules 20D are placed on the substrate 10 by die-bonding processes, wherein the electrodes on the bottom of the image sensing module 30 and the electrodes of the illumination modules 20D are electrically connected with the substrate 10 in a high-temperature soldering method. The illumination modules 20D may be arranged in positions of non-central symmetry according to requirement. The image sensing module 30 may be used as the center to divide the positions of the illumination modules 20D into a first side 201 and a second side 202, which are respectively the left side and the right side with the image sensing module 30 being the center. With respect to the illumination modules 20D, which are respectively at the first side 201 and the second side 202, the image sensing module 30 outstands in height. The image sensing module 30 is horizontally deviated from the illumination modules 20D, which are respectively at the first side 201 and the second side 202. While the miniature imaging sensor illumination package 1 is applied to an endoscope, a working channel may be formed in a position of the substrate 10, which is between the first side 201 and the second side 202 and adjacent to the image sensing module 30, whereby the instrument of the endoscope may extend to the target area for inspection. Because the miniature imaging sensor illumination package 1 has a very small volume, the distal tip of the endoscope becomes further smaller, which is helpful to increase the accuracy and comfort of medical inspection. Further, the distance between the image sensing module 30 and the illumination module 20D and the relative altitudes thereof may be precisely controlled using the metal routings (such as the conductors 100 shown in FIG. 2A) and the design of the height of supporter 220, whereby is avoided the errors likely to occur in ordinary assembly operations. Alternatively, a computer simulation may be used to obtain the optimized parameters of the configuration of the height of the surface of the sensing face 30A of the image sensing module 30 and the height of the light-emitting face 240A of the light-emitting element 240. The required height of the light-emitting element 240 may be realized by a supporter 220 fabricated independently.

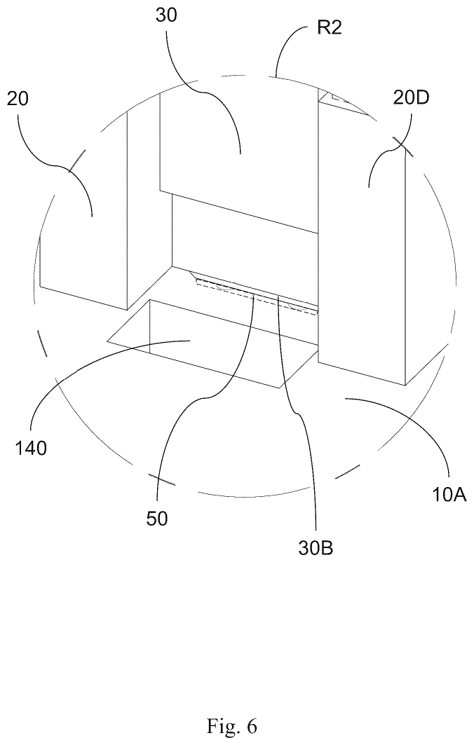

Refer to FIG. 6. FIG. 6 is an enlarged view of Local Area R2 shown in FIG. 5. The miniature imaging sensor illumination package 1 further comprises an isolation medium 50, which is filled into a space between the first surface 10A of the substrate 10 and the connection face 30B of the image sensing module 30. While a reflow process is performed between the substrate 10 and the image sensing module 30, a very small gap (a tiny structure) exists between the substrate 10 and the image sensing module 30. Once the powder, micro particles, or ashes in the environment enter the tiny structure, they may pollute the surface of the structure, affect the performance of the element, or induce defects in the fabrication process. Although a filling material may be filled into the gaps between the illumination module 20D and the image sensing module 30 of the miniature imaging sensor illumination package 1 and cured to form the encapsulating medium 40. The encapsulating medium 40 of the miniature imaging sensor illumination package 1 normally adopts a material having a high viscosity coefficient. However, a high-viscosity material is hard to flow into the tiny structure. Thus, in one embodiment, the isolation medium 50 usually adopts a material having a good flowability and a viscosity lower than that of the encapsulating medium 40. After the reflow process of the substrate 10 and the image sensing module 30, the process of filling the isolation medium 50 would prevent ashes or dirties from entering the gap.

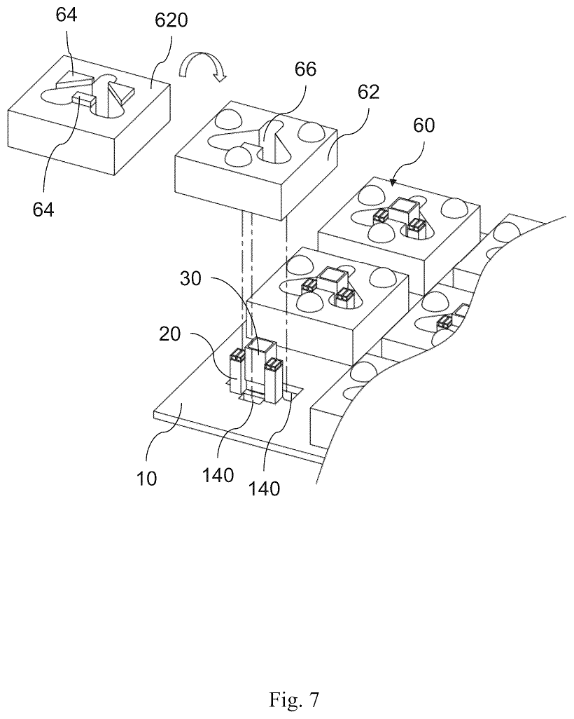

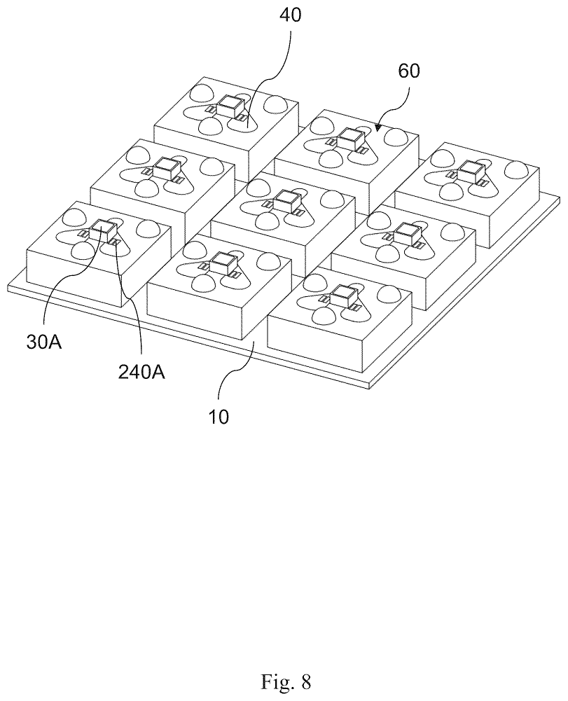

Refer to FIG. 7 and FIG. 8. The miniature imaging sensor illumination package 1 may further comprise an encapsulating mold 60, which is movably placed on the substrate 10. The encapsulating mold 60 includes a body 62, at least one insertion member 64, and a through-hole 66. The insertion members 64 are disposed on a bottom 620 of the body 62 and placed into at least one corresponding positioning hole 140. The through-hole 66 is disposed in the body 62 and neighbors the insertion member 64. The through-hole 66 may surround the illumination module 20 and the image sensing module 30. In another viewpoint, the illumination module 20 and the image sensing module 30 may be inserted into the through-hole 66. The encapsulating medium 40 is formed inside through-hole 66 and in the space between the illumination module 20 and the image sensing module 30. After the encapsulating medium 40 has been cured or after the cutting process is completed, the encapsulating mold 60 is removed.

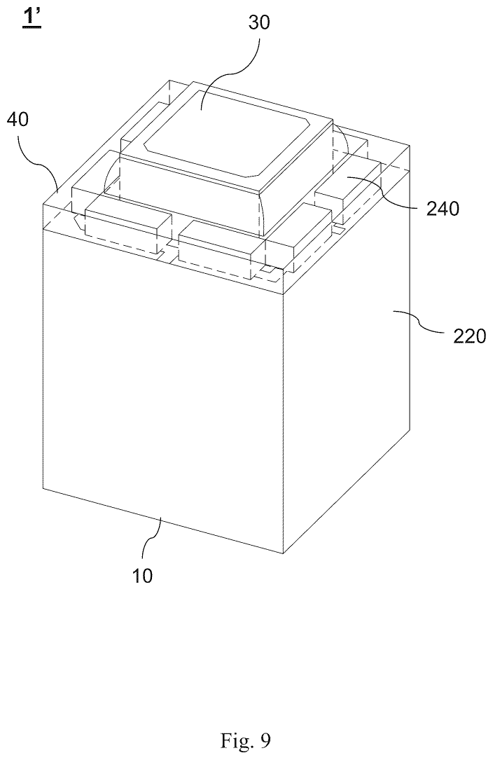

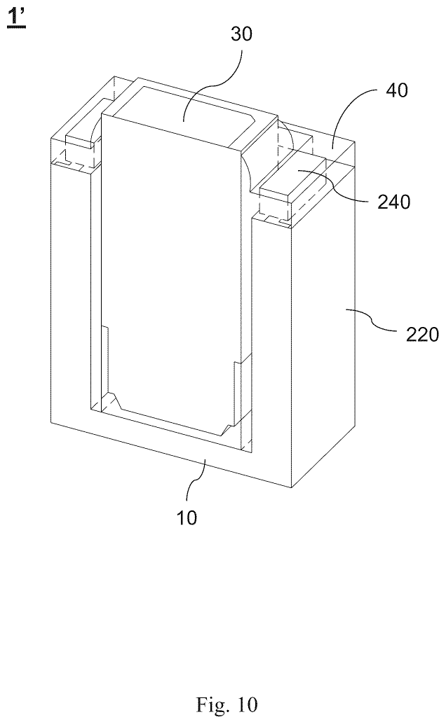

Refer to FIG. 9 and FIG. 10. The miniature imaging sensor illumination package 1′ shown in FIG. 9 and FIG. 10 is different from the abovementioned miniature imaging sensor illumination package 1 in that the light-emitting element 240 is arranged around the image sensing module 30 to form an annular structure. In the present invention, the substrate 10 and the supporters 220 of the light sources are not necessarily two independent bodies but may be an integral structure. The present invention does not constrain that the supporters 220 must be disposed on two sides of the image sensing module 30. In some embodiments, the supporters 220 may be disposed around the image sensing module 30, and the image sensing modules 30 may be connected with each other. The metal routings of the light-emitting elements 240, which are disposed on two sides or the peripheral of the image sensing module 30, may be reconfigured to form a pair of anode electrode and cathode electrode on the back side of the substrate 10, whereby the light-emitting element 240 (such as LEDs) may be driven by an identical pair of power cords. Therefore, the present invention may be exempted from the conventional technology that an LED light source needs its own power cords.

It should be noted: in some embodiments, a plurality of the abovementioned illumination modules may be simultaneously disposed on the substrate 10, such as the illumination modules 20, 20A-20D or a combination thereof, as shown in FIG. 2A and FIGS. 5-8. Further, a plurality of the abovementioned image sensing modules 30 may also be disposed on the substrate 10. The substrate 10 is cut along a plurality of cutting marks (not shown in the drawings) to form a plurality of miniature imaging sensor illumination packages having the illumination modules 20 and the image sensing modules 30. Although the cutting marks are not shown in FIG. 2A and FIGS. 5-8, the persons having ordinary knowledge in the field should be able to learn that the cutting marks are extended along the borders of the illumination module 20 and the image sensing modules 30, the borders of the positioning holes 140, or the borders of the encapsulating molds 60. Further, the persons having ordinary knowledge in the field should be able to vary the positions of the cutting marks easily according to the description and concepts of the present invention. The modules, which are arranged in array on the substrate 10, may be cut to generate many miniature imaging sensor illumination packages having a specified shape. The layouts on the substrate 10, which are shown in the abovementioned drawings, are only for exemplifications. In practical fabrication, tens to hundreds of imaging sensor illumination modules may be formed on each substrate 10. Independent miniature imaging sensor illumination packages are obtained after the cutting process. Such a measure not only simplifies the fabrication process but also raises the mass-production efficiency.

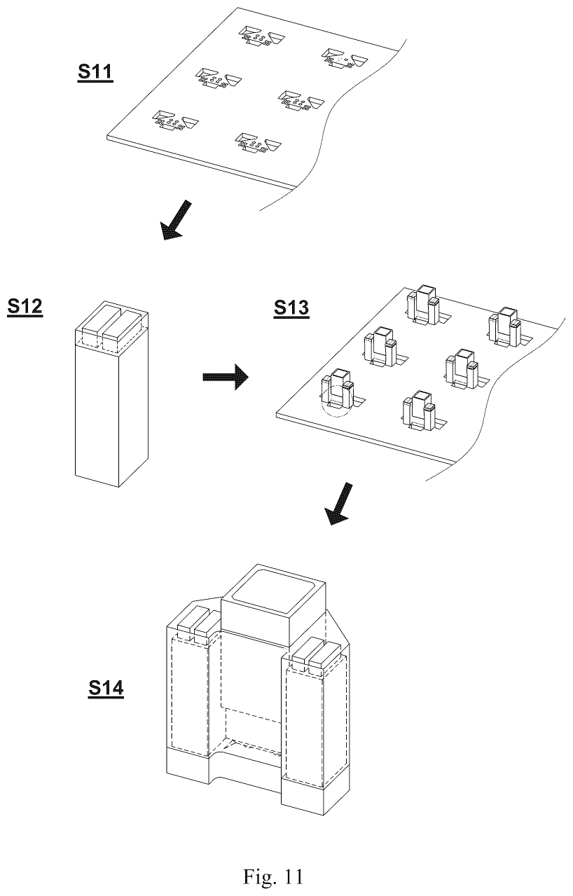

The concepts of manufacturing the miniature imaging sensor illumination packages of the present invention have been introduced during the process of describing the structure of the miniature imaging sensor illumination package. Below, FIGS. 11-15 and the explanations thereof are used to demonstrate the manufacturing process further clearly.

Refer to FIG. 11. According to one embodiment of the present invention, a manufacturing method of a miniature imaging sensor illumination package comprises
Step S11: providing a substrate, which has a plurality of conductive routings;
Step S12: disposing an illumination module on the substrate, wherein the illumination module includes at least one supporter, at least one light-emitting element, and a plurality of conductors;
Step S13: disposing an image sensing module on the substrate and near the illumination module, wherein a connection face of the image sensing module is connected with the plurality of conductive routings; a sensing face of the image sensing module is higher than a light-emitting face of the light-emitting element; and
Step S14: forming an encapsulating medium between and around the illumination module and the image sensing module.

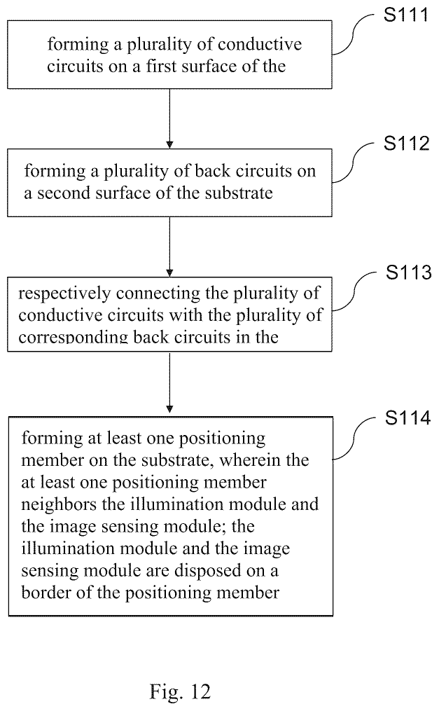

Refer to FIG. 12. Step S11 further comprises
Sub-Step S111: forming a plurality of conductive routings on a first surface of the substrate;
Sub-Step S112: forming a plurality of backside routings on a second surface of the substrate;
Sub-Step S113: respectively connecting the plurality of conductive routings with the plurality of corresponding backside routings in the interior of the substrate; and
Sub-Step S114: forming at least one positioning hole on the substrate, wherein the at least one positioning hole neighbors the illumination module and the image sensing module; the illumination module and the image sensing module are disposed on a border of the positioning hole.

The substrate may be but is not limited to a ceramic substrate, a printed circuit board (PCB), or a flexible printed circuit (FPC). The substrate has positioning holes (i.e., open holes), which are designed in advance. The front surface of the substrate has a plurality of groups of conductive routings, which are arranged in array. Each group of conductive routings has image-sensing-module conductive routings and illumination-module conductive routing. The conductive routings are connected with the backside routings through internal routings of the substrate. The backside routings are designed to meet the requirement of soldering.

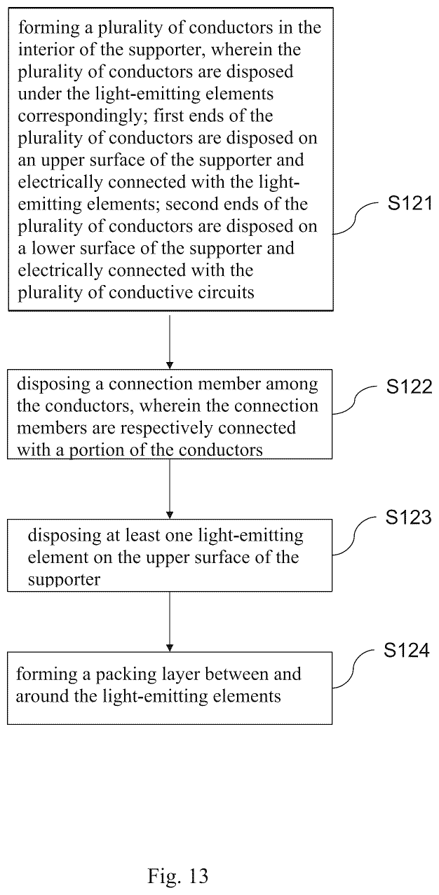

Refer to FIG. 13. Step S12 further comprises
Sub-Step S121: forming a plurality of conductors in the interior of the supporter, wherein the plurality of conductors are disposed under the light-emitting elements correspondingly; first ends of the plurality of conductors are disposed on a top surface of the supporter and electrically connected with the light-emitting elements; second ends of the plurality of conductors are disposed on a bottom surface of the supporter and electrically connected with the plurality of conductive routings;
Sub-Step S122: disposing a connection routing among the conductors, wherein the connection routings are respectively connected with a portion of the conductors;
Sub-Step S123: disposing at least one light-emitting element on the top surface of the supporter; and
Sub-Step S124: forming a packing medium between and around the light-emitting elements.

In Sub-Step S122, the connection routings may be disposed at the first ends of the plurality of conductors or the second ends of the plurality of conductors according to requirement. Alternatively, the connection routings may be disposed between the first ends and second ends of the plurality of conductors according to requirement.

In the process of manufacturing a miniature imaging sensor illumination package, the interface between the packing medium and the encapsulating medium is not necessarily visible clearly. The difference of the materials of the packing medium and the encapsulating medium may not represent different packaging surfaces. However, the persons having ordinary knowledge in the field should be able to provide different optical effects using suitable materials according to well-known technologies. Thus, it will not repeat herein.

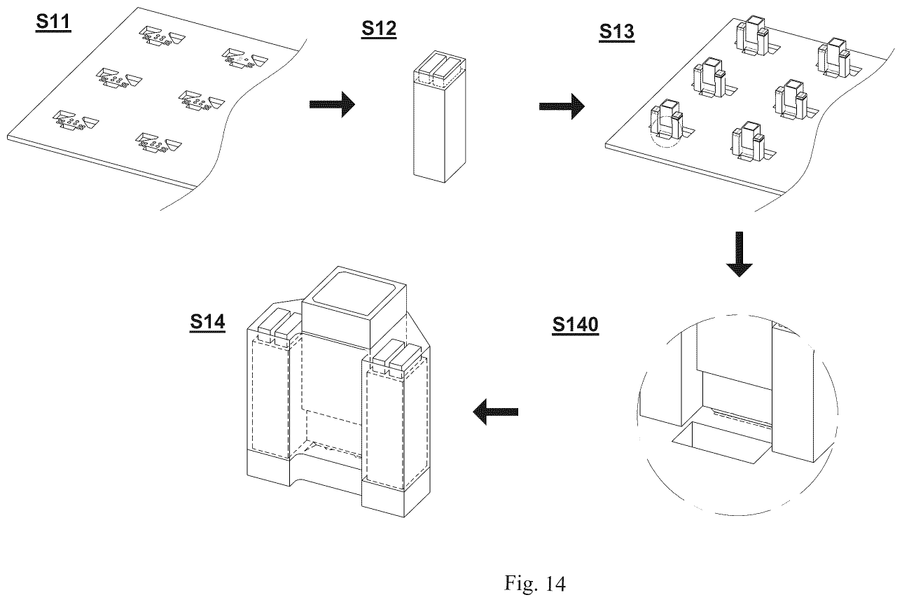

Refer to FIG. 14. The embodiment of FIG. 14 is different from the embodiment of FIG. 11 in that Step S140 is undertaken before Step S14 in FIG. 14. In Step S13, a plurality of abovementioned illumination modules and a plurality of abovementioned image sensing modules are disposed on the substrate, wherein the image sensing module neighbors the illumination module; the connection face of each image sensing module is connected with a plurality of conductive routings; the sensing face is higher than the light-emitting face of at least one light-emitting element. In Step S140, an isolation medium is filled into a space between the top surface of the substrate and the connection face of the image sensing module.

It should be easily understood by the persons having ordinary knowledge in the field: a cutting step of cutting the substrate along the cutting marks may be undertaken after Step S140. Although the cutting step is not depicted in the drawings, the persons having ordinary knowledge in the field should understand clearly that a plurality of miniature imaging sensor illumination packages each having the illumination modules and the image sensing module (as shown in Step S14) will be obtained through the cutting step.

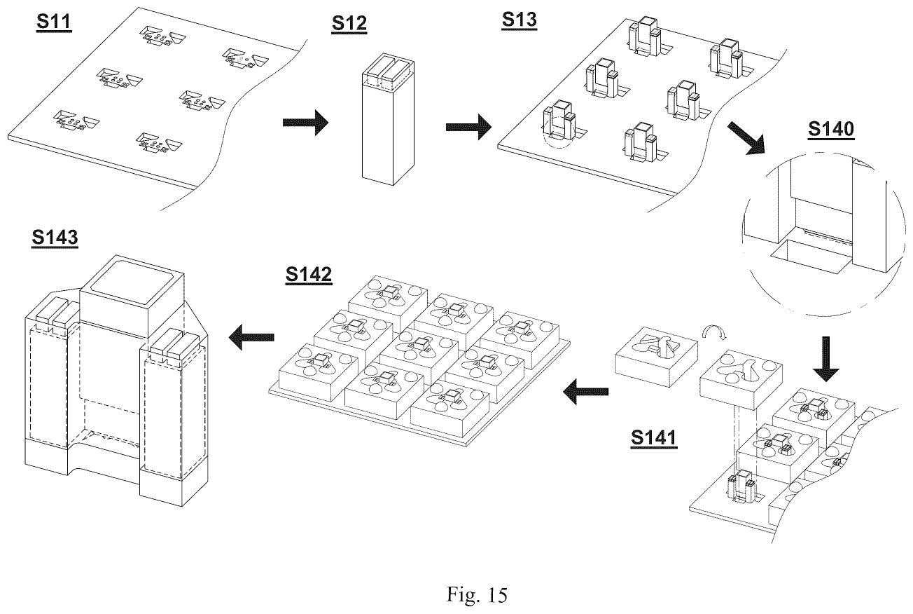

Refer to FIG. 15. The embodiment of FIG. 15 is different from the embodiment of FIG. 11 in that Steps S141-143 are undertaken after Step S140, wherein
Step S141: movably placing an encapsulating mold on the substrate, wherein the encapsulating mold includes a body, at least one insertion member, and a through-hole; the at least one insertion member is placed into at least one corresponding positioning hole; the through-hole surrounds the illumination module and the image sensing module to make the illumination module and the image sensing module be inserted into the through-hole;
Step S142: filling the encapsulating medium into the through-hole and the spaces between and around the illumination module and the image sensing module; and
Step S143: curing the encapsulating medium; after the encapsulating medium has been cured, removing the encapsulating mold and performing the cutting step.

In Step S141 where the encapsulating mold and the substrate cooperate to wok, after the packaging process and the cutting process are completed, a light source-image sensing module having a specified shape is obtained for the endoscopic applications. Further, the encapsulating mold can improve the automation of the fabrication process, raise the fabrication efficiency, and increase the consistency and precision of the miniature imaging sensor illumination packages. Even though the package demands a specified shape, the shape of the package can be easily varied using the encapsulating mold without changing the fabrication process. Therefore, the method of the present invention can effectively raise the fabrication efficiency.

The present invention proposes a miniature imaging sensor illumination package and a manufacturing method thereof, wherein even though a single routing is damaged, all the illumination light sources can still work normally. The present invention is characterized in exemption from using the conventional technology that each LED light source needs its own routing, preventing stray light from entering the image sensing module, and enhancing the adhesion of the illumination light source. The present invention not only enhances the image quality but also minimizes the size of the overall module. The present invention is very favorable for designing the bent part of the front end of an endoscope to minimize the radius of curvature.

The embodiments described above are only to exemplify the present invention but not to limit the scope of the present invention. The embodiments involving equivalent replacement or variation made easily according to the shapes, structures, characteristics, or spirits disclosed by the specification or claims are to be also included by the scope of the present invention.

While the invention is susceptible to various modifications and alternative forms, a specific example thereof has been shown in the drawings and is herein described in detail. It should be understood, however, that the invention is not to be limited to the form disclosed, but to the contrary, the invention is to cover all modifications, equivalents, and alternatives falling within the appended claims.

What is claimed is:

1. A miniature imaging sensor illumination package, comprising
a substrate, having a plurality of conductive routings and at least one positioning hole;
an illumination module, disposed on the substrate and adjacent to the at least one positioning hole and including
a supporter, having a top surface and a bottom surface, which are opposite to each other, wherein the bottom surface is disposed on the substrate;
at least one light-emitting element, disposed on the top surface of the supporter and having a light-emitting face; and
a plurality of conductors, arranged inside the supporter, located under the at least one light-emitting element, and each having a first end and a second end opposite to the first end, wherein the first end is exposed on the top surface and electrically connected with the at least one light-emitting element; the second end is exposed on the bottom surface and electrically connected with the plurality of conductive routings on the substrate; a connection routing is arranged among the plurality of conductors and respectively connected with a portion of the plurality of conductors;
an image sensing module, having a sensing face and a connection face, which are vertically opposite to each other, disposed on the substrate, adjacent to at least one positioning hole, and neighboring the illumination module, wherein the connection face is connected with the plurality of conductive routings; the sensing face is higher than the light-emitting face of the at least one light-emitting element; and
an encapsulating medium, covering spaces between and around the illumination module and the image sensing module and revealing the sensing face of the image sensing module.

2. The miniature imaging sensor illumination package according to claim 1, further comprising
an isolation medium, which is filled into a space between a top surface of the substrate and the connection face of the image sensing module.

3. The miniature imaging sensor illumination package according to claim 1, wherein the connection routing is disposed at the first ends of the plurality of conductors, or at the second ends of the plurality of conductors, or between the first ends and the second ends of the plurality of conductors.

4. The miniature imaging sensor illumination package according to claim 1, wherein the connection routing is connected with a portion of the plurality of conductors to realize parallel connection of the plurality of conductors.

5. The miniature imaging sensor illumination package according to claim 1, wherein the substrate has a first surface and a second surface, which are vertically opposite to each other; the first surface has the plurality of conductive routings; the second surface has a plurality of backside routings disposed on locations corresponding to the plurality of conductive routings; each conductive routing and the corresponding backside routing are connected to each other inside the substrate.

6. The miniature imaging sensor illumination package according to claim 1, wherein the illumination module and the image sensing module are disposed on a border of the at least one positioning hole; the at least one positioning hole is cut off in a cutting process.

7. The miniature imaging sensor illumination package according to claim 1, wherein the illumination module is disposed at a position of the substrate, which is deviated toward one side of the substrate with the image sensing module being a center.

8. The miniature imaging sensor illumination package according to claim 1, wherein the plurality of conductive routings are arranged in array and includes conductive routings for the image sensing module and conductive routings for the illumination module.

9. A manufacturing method of a miniature imaging sensor illumination package, comprising steps:
providing a substrate, which has a plurality of conductive routings and at least one positioning hole;
disposing an illumination module on the substrate, which includes at least one supporter, at least one light-emitting element and a plurality of conductors, wherein the step of disposing the illumination module on the substrate further comprises sub-steps:
forming a plurality of conductors inside the supporter, wherein the plurality of conductors is disposed under the at least one light-emitting elements correspondingly; first ends of the plurality of conductors are disposed on a top surface of the supporter and electrically connected with the at least one light-emitting element; second ends of the plurality of conductors are disposed on a bottom surface of the supporter and electrically connected with the plurality of conductive routings; a connection routing is disposed among the plurality of conductors, wherein the connection routing is respectively connected with a portion of the plurality of conductors; and
disposing the at least one light-emitting element on the top surface of the supporter;
disposing an image sensing module on the substrate and near the illumination module, wherein a connection face of the image sensing module is connected with the plurality of conductive routings; a sensing face of the image sensing module is higher than a light-emitting face of the at least one light-emitting element; and
forming an encapsulating medium between and around the illumination module and the image sensing module.

10. The manufacturing method of a miniature imaging sensor illumination package according to claim 9, wherein before the step of forming the encapsulating medium between and around the illumination module and the image sensing module is undertaken a step:
filling an isolation medium into a space between a top surface of the substrate and the connection face of the image sensing module.

11. The manufacturing method of a miniature imaging sensor illumination package according to claim 9, wherein the connection routing is disposed at the first ends of the plurality of conductors, or at the second ends of the plurality of conductors, or between the first ends and the second ends of the plurality of conductors.

12. The manufacturing method of a miniature imaging sensor illumination package according to claim 9, wherein the step of providing the substrate further comprises sub-steps:
forming the plurality of conductive routings on a first surface of the substrate;
forming a plurality of backside routings on a second surface of the substrate; and
respectively connecting the plurality of conductive routings with the plurality of corresponding backside routings inside the substrate.

13. The manufacturing method of a miniature imaging sensor illumination package according to claim 9, wherein the step of providing the substrate further comprises a sub-step:
forming at least one positioning hole on the substrate, wherein the at least one positioning hole neighbors the illumination module and the image sensing module; the illumination module and the image sensing module are disposed on a border of the at least one positioning hole.

14. The manufacturing method of a miniature imaging sensor illumination package according to claim 13, wherein after the step of disposing the image sensing module on the substrate are undertaken steps:
placing an encapsulating mold on the substrate, wherein the encapsulating mold includes a body and a through-hole; the through-hole penetrates the body and surrounds the illumination module and the image sensing module to enable the illumination module and the image sensing module to be inserted into the through-hole;
filling the encapsulating medium into the through-hole and the spaces between and around the illumination module and the image sensing module; and
curing the encapsulating medium; after the encapsulating medium has been cured or after a cutting process, removing the encapsulating mold.

15. The manufacturing method of a miniature imaging sensor illumination package according to claim 14, wherein the encapsulating mold further includes at least one insertion member, which is disposed on a bottom of the body and placed into the at least one positioning hole correspondingly; a border of the through-hole neighbors the at least one insertion member; the encapsulating medium is disposed inside the through-hole and in spaces between and around the illumination module and the image sensing module; after the encapsulating medium has been cured or after a cutting process, the encapsulating mold is removed.

16. A manufacturing method of a miniature imaging sensor illumination package, comprising steps:
providing a substrate, which has a plurality of conductive routings and a plurality of positioning holes;
disposing on the substrate the plurality of illumination modules of claim 1 and the plurality of image sensing modules of claim 1, wherein the image sensing module neighbors the illumination module; the connection face of each of the plurality of the image sensing modules is connected with the plurality of conductive routings; the sensing face is higher than the light-emitting face of the at least one light-emitting element; and
cutting the substrate along a plurality of cutting marks to form a plurality of miniature imaging sensor illumination packages each having the image sensing module and the illumination modules.
